(19) United States
(12) Patent Application Publication
(10) Pub. No.: US 2013/0284090 A1
(43) Pub. Date: Oct. 31, 2013

(54) COMPENSATING CONCENTRATION UNCERTAINITY

(71) Applicants: Ganesh BALASUBRAMANIAN, Sunnyvale, CA (US); Martin Jay SEAMONS, San Jose, CA (US); Kaushik ALAYAVALLI, Santa Clara, CA (US); Kwangduk Douglas LEE, Redwood City, CA (US); Wendy H. YEH, Mountain View, CA (US); Sudha RATHI, San Jose, CA (US); Krishna VIJAYARAGHAVAN, Burnaby (CA); Chiu CHAN, Foster City, CA (US)

(72) Inventors: Ganesh BALASUBRAMANIAN, Sunnyvale, CA (US); Martin Jay SEAMONS, San Jose, CA (US); Kaushik ALAYAVALLI, Santa Clara, CA (US); Kwangduk Douglas LEE, Redwood City, CA (US); Wendy H. YEH, Mountain View, CA (US); Sudha RATHI, San Jose, CA (US); Krishna VIJAYARAGHAVAN, Burnaby (CA); Chiu CHAN, Foster City, CA (US)

(21) Appl. No.: 13/864,911

(22) Filed: Apr. 17, 2013

Related U.S. Application Data
(60) Provisional application No. 61/638,626, filed on Apr. 26, 2012.
(60) Provisional application No. 61/638,958, filed on Apr. 26, 2012.

(51) Int. Cl. C23C 16/455

(52) U.S. Cl. CPC C23C 16/45512
USPC 118/712; 137/561 R; 137/10

(57) ABSTRACT

Methods and apparatus for depositing uniform boron-containing films are disclosed. A first precursor is delivered to a chamber through a first pathway having a first flow controller and a composition sensor. A second precursor is delivered by a second pathway, including a second flow controller, to a mixing point fluidly coupling the first and second pathways. A controller is coupled to the vibration sensor and the first and second flow controllers. The first precursor may be a mixture of diborane and a diluent gas, and the second precursor is typically a diluent gas. The flow rate of the first precursor may be set by determining a concentration of diborane in the first precursor from the composition sensor reading, and setting the flow rate to maintain a desired flow rate of diborane. The flow rate of the second precursor may be set to maintain a desired flow to the chamber.

### CROSS-REFERENCE TO RELATED APPLICATIONS

This application claims benefit of U.S. Provisional Patent Application Ser. No. 61/638,626, filed Apr. 26, 2012, and United States Provisional Patent Application Ser. No. 61/638,958, filed Apr. 26, 2012, both of which are incorporated herein by reference.

### FIELD

Embodiments described herein generally relate to methods and apparatus for depositing boron-containing films. More specifically, embodiments described herein relate to methods and apparatus for providing deposition precursors to a deposition apparatus.

### BACKGROUND

Boron is an important material in semiconductor manufacturing. Boron-containing films are used as doping materials, masking materials, and insulating materials at various stages of semiconductor manufacturing processes. A boron film may be deposited on a semiconductor as a dopant source. A boron-nitride film may be deposited as a mask material or as an insulating material. Boron-carbon films may be used as a mask material.

A typical process for forming a boron-containing film involves using diborane as a boron source. Diborane is provided to a processing area, sometimes with another precursor, and boron from the diborane is deposited on the substrate. The diborane is subjected to a reactive transformation designed to exploit the peculiar energy configuration of the diborane molecule and extract the boron onto the substrate.

Diborane is a dimer of borane, and the two exist in pseudo-equilibrium. Diborane is most commonly used for deposition processes because it is easy to store and transport, and may be vaporized during processing. Over time, however, diborane equilibrates to borane to some degree, and to other borane oligomers, reducing the amount of diborane in the precursor. As the amount of diborane in the precursor is reduced, the amount of boron available from the reactive transformation drifts, and the deposition process is non-uniform.

Because uniformity is an increasingly important feature of processes that manufacture semiconductor devices of diminishing size, there is a need for methods and apparatus that control boron deposition processes as concentration of diborane in the precursor drifts.

### SUMMARY

Embodiments of the invention generally relate to methods and apparatus for depositing uniform boron-containing films. A first precursor is delivered to a processing chamber through a first pathway comprising a first flow controller and a composition sensor. A second precursor is delivered by a second pathway to a mixing point fluidly coupling the first and second pathways. The second pathway includes a second flow controller. A controller is coupled to the composition sensor, the first flow controller, and a second flow controller. The first precursor is typically a gas mixture of a boron source, such as diborane, and a diluent gas, and the second precursor is typically a diluent gas. The flow rate of the first precursor may be set by determining a concentration of boron in the first precursor from the composition sensor reading, and setting the flow rate to maintain a desired flow rate of boron. The flow rate of the second precursor may then be set to maintain a constant gas flow to the processing chamber.

The composition sensor may be a spectroscopic sensor, such as an infrared sensor or mass spectrometer, or a vibration sensor, which may be an acoustic sensor, such as a pressure or motion sensor, for example a piezoelectric sensor such as a Piezocon. Remotely operated valves may be signalled by an electronic controller to control the precursor flow rates.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a process diagram illustrating a processing system according to one embodiment.

FIG. 2 is a flow diagram summarizing a method according to another embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

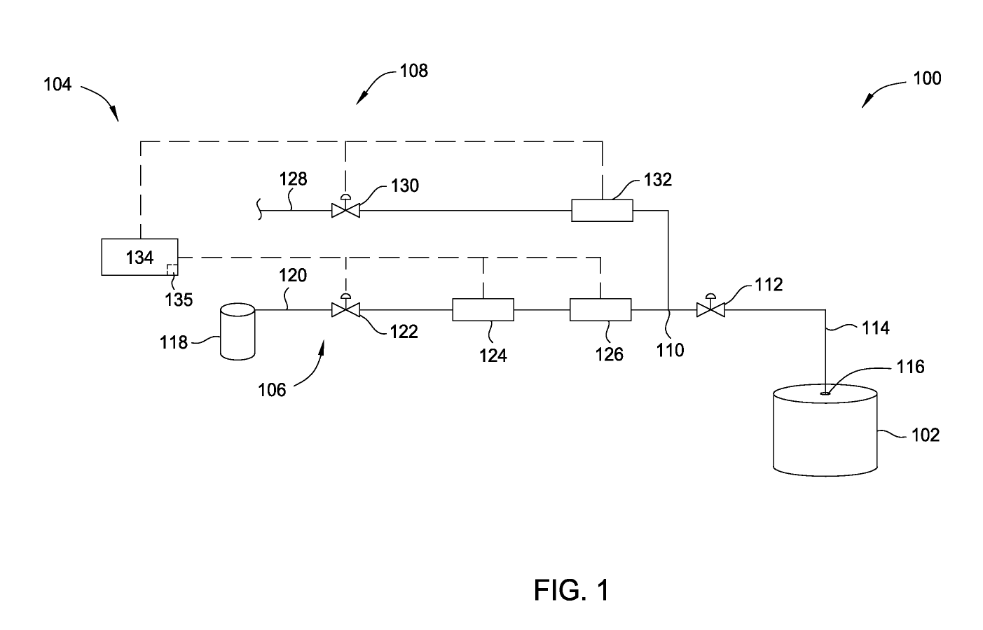

FIG. 1 is a process diagram illustrating a processing system 100 according to one embodiment. The processing system 100 of FIG. 1 is useful for performing a process involving maintaining a flow rate of a particular component of a precursor mixture as the concentration of that component in the mixture changes. The processing system 100 includes a processing chamber 102, which may be any suitable processing chamber, and a precursor delivery system 104. Exemplary chambers include any of the PRODUCER® chambers available from Applied Materials, Inc., of Santa Clara, Calif.

The precursor delivery system 104 includes a first pathway 106 for flowing a first precursor to the processing chamber 102 and a second pathway 108 for flowing a second precursor to the processing chamber. The first pathway 106 and the second pathway 108 join at a mixing point 110, where the first and second precursors mix, flow through a shutoff valve 112 to the processing chamber 102 at a portal 116 via a conduit 114.

A source 118 of the first precursor is coupled into the first pathway 106 by a conduit 120 that flows the first precursor from the first precursor source 118 to a first control valve 122. A composition sensor 124 is disposed in the first pathway to detect a concentration of a desired component in the first precursor. A first flow controller 126 senses the flow rate of the first precursor. A second flow controller 132 senses the flow rate of the second precursor through a second valve 130 from a conduit 128 coupled to a second precursor source (not shown).

The composition sensor 124 may be a spectrographic sensor, such as a mass spectrometer or infrared sensor, or a vibration sensor, which may be a pressure sensor or a motion sensor. An example of a pressure sensor is a piezoelectric sensor such as a Piezocon. An example of a motion sensor is a diaphragm sensor. A chromatographic sensor such as a gas chromatograph may also be used. In most cases, the composition sensor 124 will have relative precision of about 1% to afford good control of the chemical process being performed in the processing chamber. For example, with a precision of 1%, the composition sensor 124 may register a concentration of 10.0% or a concentration of 10.1% or a concentration of 9.9%, thus precisely tracking minor changes in concentration.

The composition sensor 124 sends a signal to a controller 134 that relates the signal from the composition sensor 124 to density of the material flowing across the composition sensor 124. The controller 134 may have a composition signal processor 135 dedicated to processing a signal from the composition sensor 124 and passing composition data to other portions of the controller 134. If the composition sensor 124 is a Piezocon, the composition signal processor 135 may be a Piezocon controller. From the composition registered by the composition sensor 124, the density of the material may then be related to a concentration of known components of the first precursor. For example, if the first precursor is a gas mixture of diborane in helium, a slight change in overall density of the mixture indicates a drift in concentration of diborane in the helium.

Flow sensors 126 and 132 register flow rates of the first precursor and the second precursor, respectively, to the controller 134. Based on the concentration signal sent by the composition sensor 124, the controller 134 may adjust flow of the first precursor by manipulating a control valve 122 to maintain a desired flow of the key ingredient, for example diborane, to the process chamber 102 as the concentration changes. The controller 134 may also adjust flow of the second precursor by manipulating a second control valve 130 to maintain a desired total gas flow to the chamber 102. The control valve 122 is shown between the precursor source 118 and the composition sensor 124 in FIG. 1, but the control valve 122 may be located anywhere along the first pathway 106. The control valve 122 may also be integrated with the flow sensor 126 to form a flow controller that sends signals to, and receives signals from, the controller 134 and controls flow of the first precursor. The control valve 130 and the flow sensor 132 may likewise be integrated into a flow controller that communicates with the controller 134 and controls flow of the second precursor.

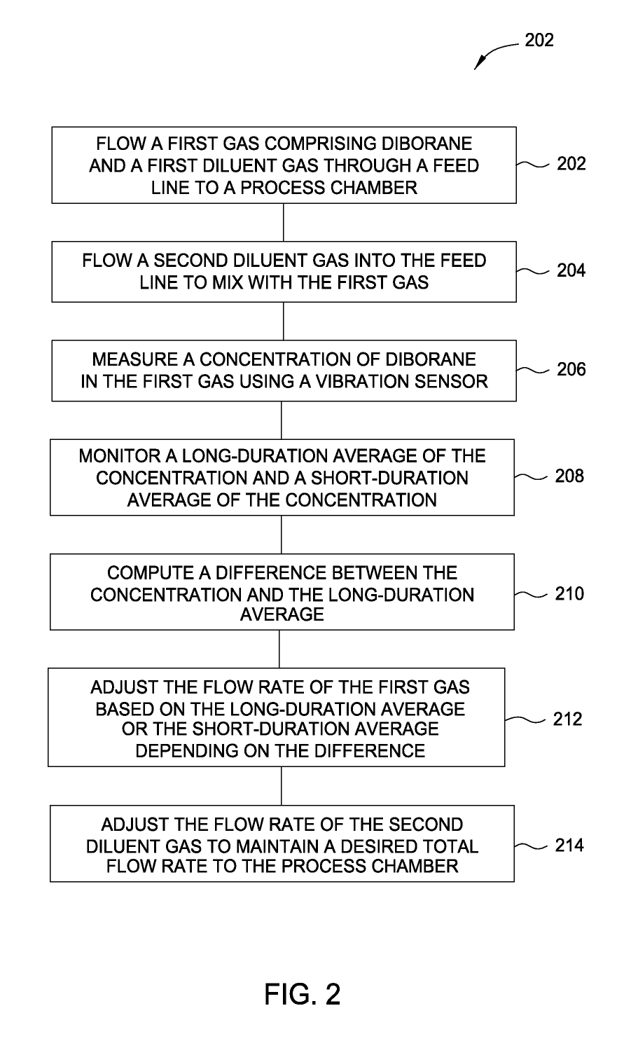

FIG. 2 is a flow diagram summarizing a method 200 according to another embodiment. The method 200 may be practiced using the apparatus 100 of FIG. 1. At 202, a first gas comprising diborane and a first diluent gas is provided through a feed line into a processing chamber. At 204, a second diluent gas is flowed into the feed line to mix with the first gas.

At 206, a concentration of diborane in the first gas is measured using a composition sensor. The composition sensor may be a spectrographic sensor or a vibration sensor, as described above in connection with FIG. 1. The signal is then converted to a concentration based on a known relation to density of the gas, and then to concentration via gas law relations.

As gas flows across the composition sensor, the sensor signal is sampled at regular intervals. An average of the concentration derived from the sensor signal over a long duration, such as 60 seconds, and over a short duration, such as three seconds, is maintained at 208. At 210, the difference between the concentration detected at each interval and the long duration average is computed as an indication of change in the concentration of diborane in the first gas.

At 212, the flow rate of the first gas is adjusted based on the long duration average or the short duration average of the concentration, depending on the difference obtained in 210. If the difference is relatively large, a large or fast deviation from a target flow rate is indicated, so while the difference is above a certain threshhold, the short duration average of concentration is used to determine flow set points, in order to track the rapidly changing concentration and maintain the flow rate of diborane at a desired level. If the difference is relatively small, less than the threshhold level, the long duration average is used to minimize changes to the flow rate.

At 214, the flow rate of the second diluent gas is adjusted based on the flow rate of the first gas to maintain a desired total gas flow rate to the process chamber.

In one example, using the apparatus similar to that of FIG. 1 with a piezoelectric pressure sensor for monitoring concentration, a precursor mixture of diborane in helium is flowed through the first pathway to a process chamber. The concentration of diborane in helium is nominally about 10 wt %, but the precursor delivery system described herein accommodates variation in source concentration. Helium gas is provided through the second pathway.

The concentration of diborane in the precursor is monitored using the piezoelectric sensor. A three-second moving average of the concentration and a 60-second moving average of the concentration are maintained by the controller. Each instantaneous reading of the concentration is compared to the 60-second moving average, and the deviation from the 60-second moving average is monitored. The flow rate of the diborane containing precursor is determined as follows:

F_{P}=F_{T}(X_{T}/(1+X_{T}))*(1+1/X_{P})

where F_{P} is the desired flow rate of the diborane containing precursor, F_{T} is the desired total gas flow rate to the processing chamber, X_{T} is the target concentration of diborane in the gas flowing into the processing chamber, and X_{P} is the concentration of diborane in the diborane containing precursor.

The concentration used by the controller to determine the target flow rate F_{P} depends on the deviation of instantaneous concentration from the 60-second moving average. If the deviation is greater than 0.001, the three-second moving average is used so that the controller adjusts the flow rate more quickly to compensate for rapidly changing concentration in the precursor. If the deviation is less than 0.001, the 60-second moving average is used so that flow adjustments are smaller. The flow of helium through the second pathway is adjusted to compensate for flow adjustments to the diborane containing precursor such that the total gas flow rate is maintained at or near the target rate F_{T}.

Such a control method is useful to compensate for drift in diborane concentration of the precursor as diborane decomposes to borane and other borane oligomers, and to compensate for disruptive process events such as RF strikes and changes in precursor source ampoules, which typically have varying concentration of diborane. Using such methods, variation in concentration of diborane in the processing chamber is minimized and uniform processing is achieved.

It should be noted that although the foregoing example discusses use of the apparatus and methods described herein in the context of flowing diborane and helium into a processing chamber, the same or similar apparatus and methods may be used for controlling concentration of hydrocarbon feeds flowing to a processing chamber in a diluent such as hydrogen for depositing carbon containing films such as amorphous carbon. Although hydrocarbon species such as C₁-C₄ hydrocarbons, for example, acetylene, ethylene, and propylene in a hydrogen or helium diluent gas, are not as unstable over time as diborane, variation in source concentration may be compensated using the methods and apparatus described herein.

Diluent gases other than helium may be used with the apparatus and methods described herein. Hydrogen gas, argon, and nitrogen may be used, depending on the precursor. Generally, a substantial difference in molecular weight between the precursor and the diluent gas is desired to afford accurate monitoring of concentration, and the diluent gas generally has a desired chemical reactivity or inertness in the processing chamber. In the example described above, where the first precursor is diborane flowing in helium, the second precursor may be a diluent other than helium, such as nitrogen, or hydrogen, depending on the processing conditions in the chamber. The diluent for the first precursor may likewise be something other than helium, for example nitrogen or hydrogen.

While the foregoing is directed to embodiments of the present invention, other and further embodiments of the invention may be devised without departing from the basic scope thereof, and the scope thereof is determined by the claims that follow.

We claim:

1. A precursor delivery apparatus, comprising:
a first precursor delivery pathway comprising a first flow controller and a vibration sensor;
a second precursor delivery pathway comprising a second flow controller;
a mixing point fluidly coupling the first precursor delivery pathway and the second precursor delivery pathway; and
a controller coupled to the first flow controller, the second flow controller, and the vibration sensor.

2. The precursor delivery apparatus of claim 1, wherein the vibration sensor is a pressure sensor.

3. The precursor delivery apparatus of claim 1, wherein the vibration sensor is a piezoelectric device.

4. The precursor delivery apparatus of claim 1, further comprising a back-pressure regulator fluidly coupled to the mixing point.

5. An apparatus for forming a boron-containing film, comprising:
a processing chamber; and
a precursor delivery system coupled to the processing chamber, the precursor delivery system comprising:
a first precursor delivery pathway comprising a first flow controller and a composition sensor;
a second precursor delivery pathway comprising a second flow controller;
a mixing point fluidly coupling the first precursor delivery pathway, the second precursor delivery pathway, and the processing chamber; and
a controller coupled to the first flow controller, the second flow controller, and the vibration sensor.

6. The apparatus of claim 5, wherein the composition sensor is a pressure sensor, a piezoelectric device, a vibration sensor, a mass spectrometer, or a gas chromatograph.

7. The apparatus of claim 5, wherein the composition sensor is a piezoelectric device.

8. The apparatus of claim 5, wherein the composition sensor is a vibration sensor.

9. A method of controlling delivery of diborane to a processing chamber, the method comprising:
flowing a gas mixture comprising diborane and a diluent gas through a first pathway to the processing chamber;
flowing a diluent gas through a second pathway to the processing chamber, the second pathway intersecting with the first pathway at a mixing point;
sensing a flow rate of the gas mixture and the diluent gas;
sensing a density of the gas mixture and determining a concentration of diborane in the gas mixture from the density of the gas mixture;
adjusting a flow rate of the gas mixture based on a desired flow rate of diborane; and
adjusting a flow rate of the diluent gas based on a desired total gas flow rate to the processing chamber.

10. The method of claim 9, wherein sensing a density of the gas mixture comprises sensing vibration of the first pathway.

11. The method of claim 9, wherein adjusting the flow rate of the gas mixture comprises maintaining a long-duration average of the concentration and a short-duration average of the concentration.

12. The method of claim 11, wherein adjusting the flow rate of the gas mixture further comprises determining a difference between the concentration and the long-duration average.

13. The method of claim 12, wherein adjusting the flow rate of the gas mixture further comprises determining a target flow rate of the gas mixture based on the long-duration average or the short-duration average depending on the difference.

14. The method of claim 12, wherein adjusting the flow rate of the gas mixture further comprising computing a difference between the long-duration average to the short-duration average and comparing the difference to a threshhold value.

15. The method of claim 14, wherein adjusting the flow rate of the gas mixture further comprises comparing the long-duration average to a target value if the difference is less than the threshhold value and comparing the short-duration average to the target value if the difference is greater than the threshhold value.
